(19) United States
(12) Patent Application Publication
(10) Pub. No.: US 2025/0015127 A1
(43) Pub. Date: Jan. 9, 2025

(54) SEMICONDUCTOR DEVICE HAVING LOW-RESISTANCE GATE CONNECTOR

(71) Applicant: Taiwan Semiconductor Manufacturing Company, Ltd., Hsinchu (TW)

(72) Inventors: Tien Yu Chu, Taichung City (TW); Yi-Li Huang, Hsinchu County (TW); Hui-Hsuan Kung, Taichung City (TW); Chih-Hsiao Chen, Taichung City (TW)

(21) Appl. No.: 18/346,772

(22) Filed: Jul. 3, 2023

(51) Int. Cl. H01L 29/06; H01L 27/088; H01L 29/08; H01L 29/78; H01L 29/786

(52) U.S. Cl. CPC H01L 29/0615; H01L 27/0886; H01L 29/0865; H01L 29/0882; H01L 29/7827; H01L 29/7856; H01L 29/7869

(57) ABSTRACT

Semiconductor devices are provided. In one example, a semiconductor device includes: a substrate, a first circuit region and a second circuit region extending in a first direction, and a gate structure extending in a second direction that is substantially perpendicular to the first direction. The gate structure further includes: two gate electrode sections respectively located in the first and second circuit regions, and a low-resistance section between and interconnecting the two gate electrode sections. The two gate electrode sections are configured as gate electrodes for two transistors respectively located in the first and second circuit regions. The two gate electrodes have a first width (W₀) along the first direction, the low-resistance section has a second width (W) along the first direction, and a ratio of W to W₀ (W/W₀) is at least 1.1.

### FIELD

Embodiments of the present disclosure relate generally to semiconductor devices, and more particularly to field effect transistor (FET) devices.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. There is always a need to improve the performance of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram illustrating a top view of a layout of a semiconductor device, in accordance with some embodiments.

FIG. 1B is a schematic diagram illustrating a cross-sectional view of the semiconductor device of FIG. 1A, in accordance with some embodiments.

FIG. 1C is a schematic diagram illustrating another cross-sectional view of the semiconductor device of FIG. 1A, in accordance with some embodiments.

FIG. 1D is a schematic diagram illustrating a top view of a layout of another semiconductor device, in accordance with some embodiments.

FIG. 1E is a schematic diagram illustrating a cross-sectional view of the semiconductor device of FIG. 1D, in accordance with some embodiments.

FIG. 1F is a schematic diagram illustrating a top view of a layout of another semiconductor device, in accordance with some embodiments.

FIG. 1G is a schematic diagram illustrating a cross-sectional view of the semiconductor device of FIG. 1F, in accordance with some embodiments.

FIG. 2A is a schematic diagram illustrating a top view of a layout of another semiconductor device, in accordance with some embodiments.

FIG. 2B is a schematic diagram illustrating a top view of a layout of another semiconductor device, in accordance with some embodiments.

FIG. 2C is a schematic diagram illustrating a top view of a layout of another semiconductor device, in accordance with some embodiments.

FIG. 2D is a schematic diagram illustrating a top view of a layout of another semiconductor device, in accordance with some embodiments.

FIG. 3 is a schematic diagram illustrating a top view of a layout of another semiconductor device, in accordance with some embodiments.

FIG. 4 is a schematic diagram illustrating a top view of a layout of another semiconductor device, in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and may not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

In recent development of semiconductor devices, particularly semiconductor devices having multiple active regions and transistors, gate connectors are often used to interconnect gate electrodes of transistors in different active regions. According to some embodiments of the present disclosure, a gate structure may have two gate electrode sections and a middle section that connects the two gate electrode sections. The two gate electrode sections may function as two gate electrodes respectively for two different transistors of a semiconductor device. Conventionally, the gate structure is homogeneous in composition. In other words, the gate electrode sections and the middle section are composed of the same material. A typical material of the homogenous gate structure is a work function metal, which usually has a relatively high resistivity. The overall resistance of the homogenous gate structure may be very high, at least in part due to the high resistivity of the middle section. The high resistance of the gate structure may cause many problems, such as overheating, unfavorable power dissipation, and low durability of functional elements in the semiconductor device.

In addition, an inter-layer dielectric (ILD) layer is usually formed to surround the gate structure and other conductive elements in the semiconductor device, according to some embodiments of the present disclosure. A conventional ILD layer is typically homogenous in composition and composed of a dielectric material having a relatively high dielectric constant (e.g., silicon dioxide). Parasitic capacitance may be generated between the gate structure and another conductive element proximate to the gate structure, at least in part due to the ILD layer filling in the gap therebetween. The parasitic capacitance is highly unfavorable and may also interfere with the nearby transistors and/or cause problems with the proper function of the active elements.

The present disclosure provides techniques to address the above-mentioned challenges. One insight provided in the present disclosure is related to a novel heterogeneous gate structure having a low-resistance section that connects the two gate electrode sections. According to some embodiments, the low-resistance section of the heterogeneous gate structure may have an enlarged width or cross-sectional dimension, compared with the gate electrode sections. The overall resistance of the heterogeneous gate structure can be significantly lowered due to the enlarged dimension of the low-resistance section, as compared with the conventional homogenous gate structure. According to some embodiments, the low-resistance section of the heterogeneous gate structure may be composed of a low-resistivity material that is different from the material of the gate electrode sections. The low-resistivity material may also contribute to the reduction of resistance for the heterogeneous gate structure. According to some embodiments, the low-resistance section may have a combination of both an enlarged dimension and a low-resistivity material. According to some embodiments, the semiconductor device may include multiple heterogeneous gate structures having the low-resistance section. The multiple low-resistance sections may significantly reduce the overall power dissipation and improve the performance of the semiconductor device.

Another insight provided in the present disclosure is a heterogeneous inter-layer dielectric (ILD) layer having different ILD structures that surround different sections of the heterogeneous gate structure in the semiconductor device. According to some embodiments, a heterogeneous ILD layer includes a first ILD structure that surrounds the gate electrode sections and a second ILD structure that surround the low-resistance section. The second ILD structure may be composed of a dielectric material having a relatively low dielectric constant and/or a relatively high dielectric strength, compared with the first ILD structure. The second ILD structure may fill a gap between two adjacent low-resistance sections or between a low-resistance section and another conductive element (e.g., a metal contact) adjacent to the low-resistance section. Accordingly, parasitic capacitance between the two adjacent low-resistance sections or between the low-resistance section and another conductive element may be significantly reduced. Additionally, the risk for electrical breakdown between the low-resistance section and another conductive element may be reduced or prevented due to the relatively high dielectric strength of the second ILD structure.

Example Semiconductor Devices with Heterogeneous Gate Structure

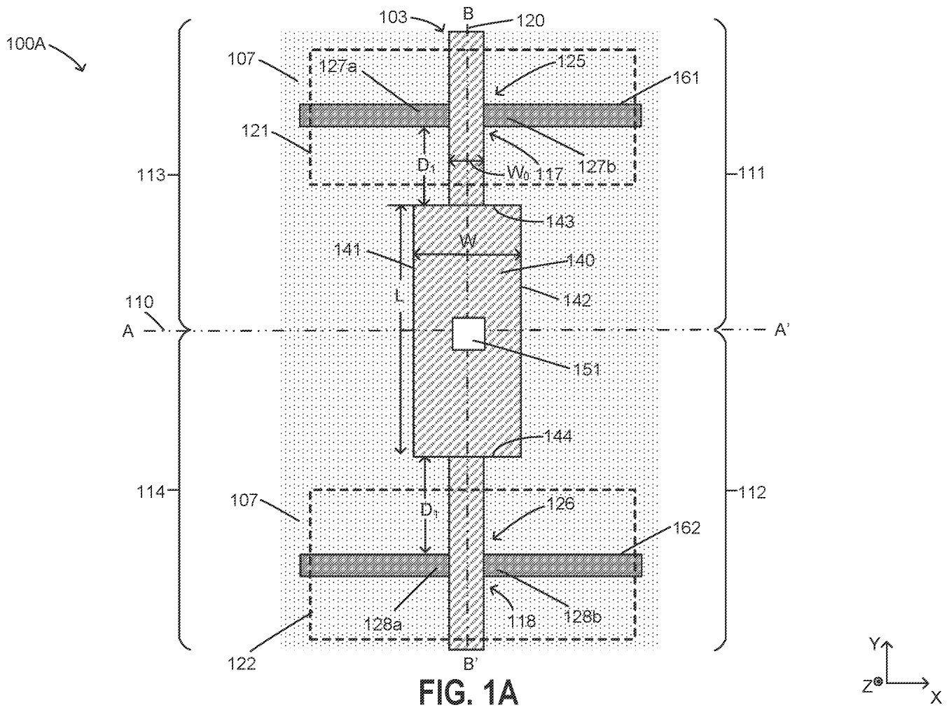

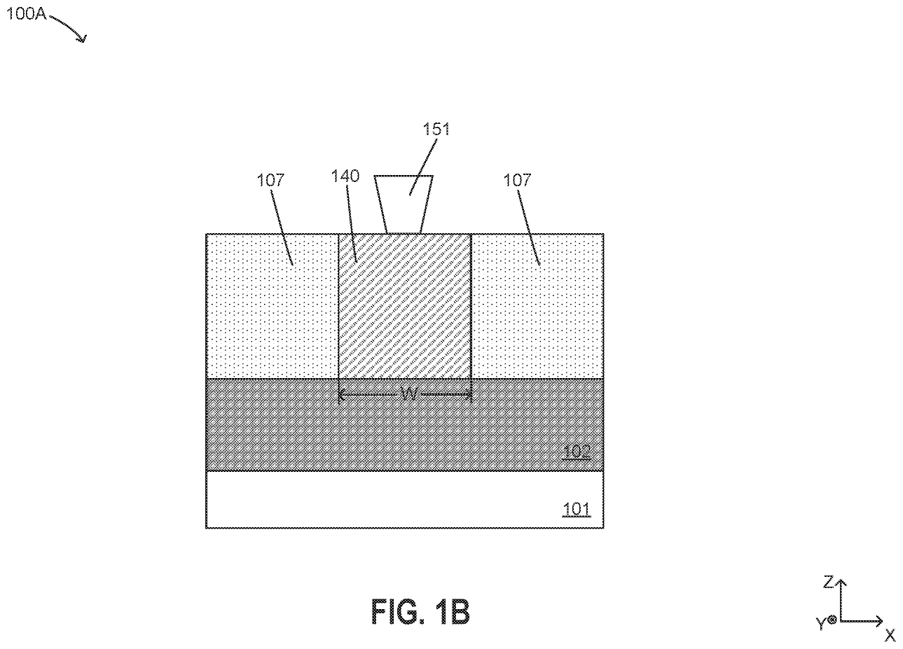

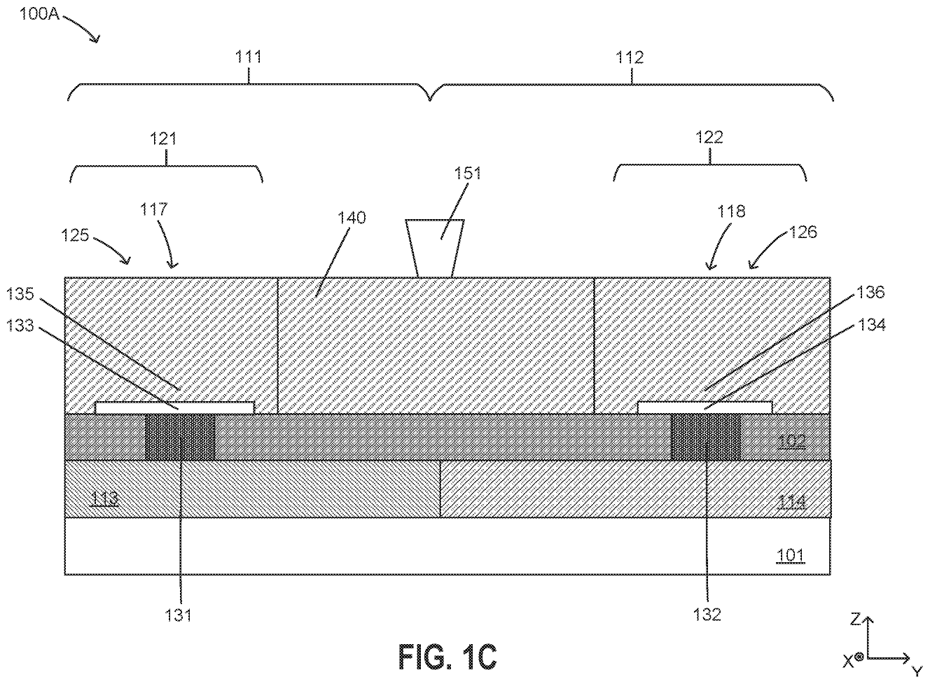

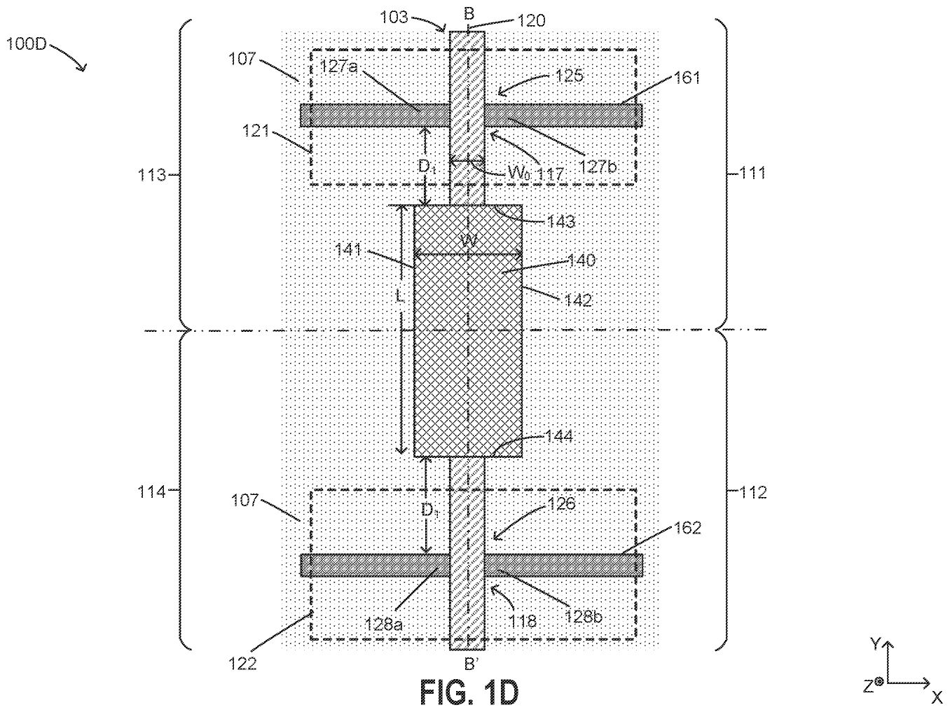

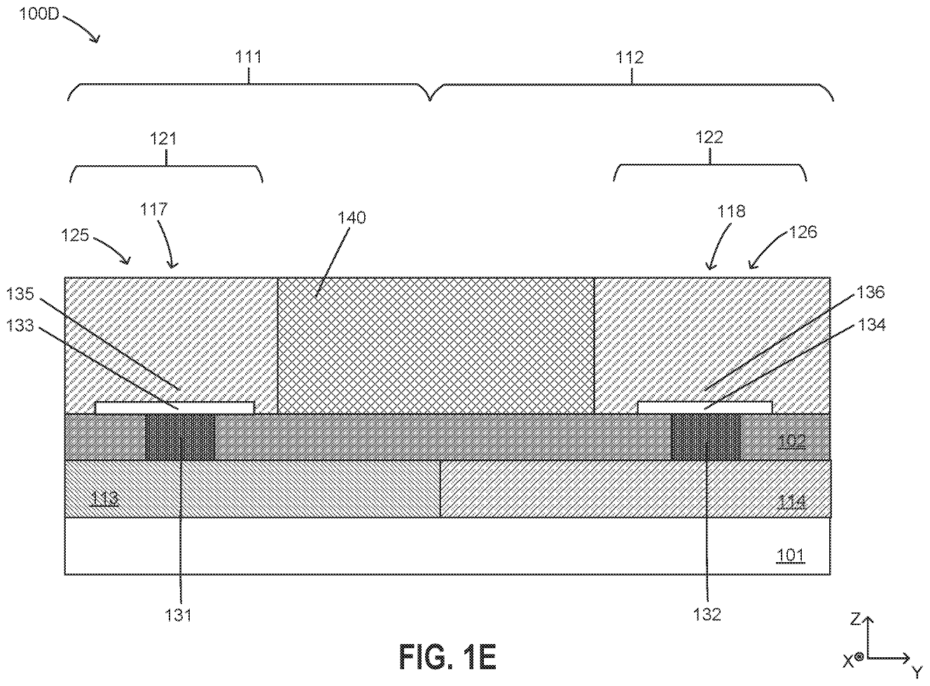

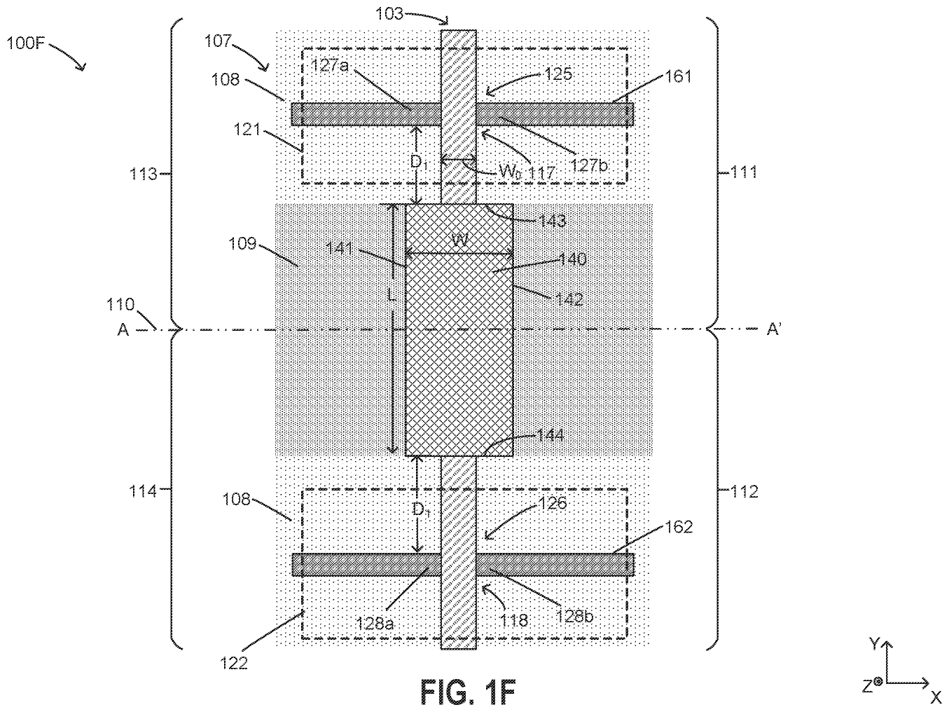

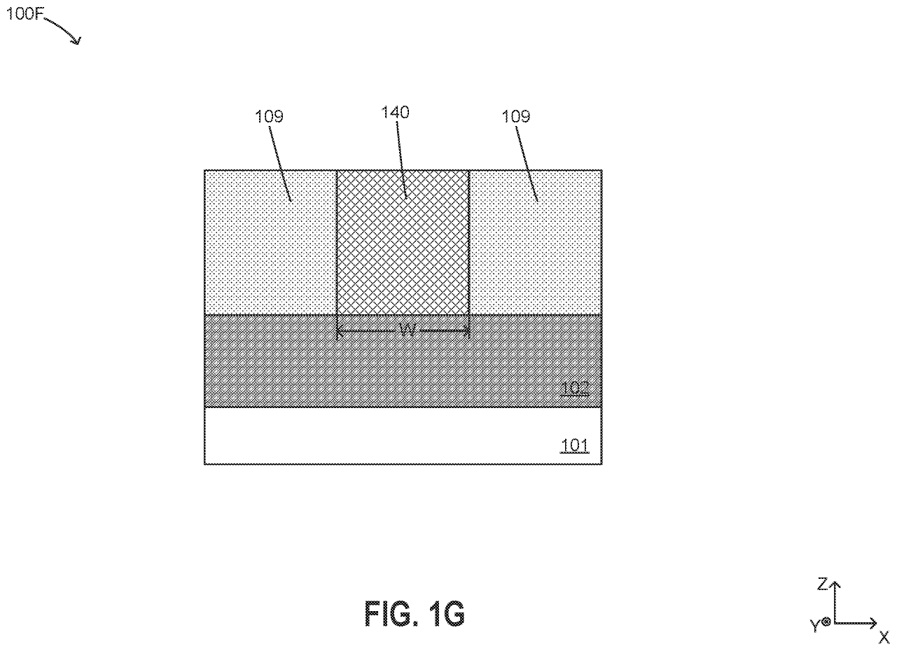

FIG. 1A is a top view of a layout of a semiconductor device 100A, in accordance with some embodiments. FIG. 1B is a cross-sectional view of the semiconductor device 100A along an imaginary line 110 from A to A′ in a first direction (i.e., the latitudinal direction or X-direction). FIG. 1C is a cross-sectional view of the semiconductor device 100A along an imaginary line 120 from B to B′ in a second direction (i.e., the longitudinal direction or Y-direction). In the illustrated example, the layout of semiconductor device 100A includes, among other components or elements, a substrate 101, a plurality of active regions including a first active region 111 and a second active region 112, at least two transistors 125 and 126, and at least one heterogeneous gate structure 103 having a low-resistance section 140. The term “low-resistance section” used herein also refers to “low-resistance connector,” “low-resistance gate connector,” “low-resistance gate connector section,” or an equivalent thereof.

Various components or elements of the semiconductor device 100A are formed on the substrate 101. The elements of the semiconductor device 100A include active elements and/or passive elements. In at least one embodiment, active elements are arranged in a circuit region or a transistor region of the semiconductor device to provide one or more functions and/or operations intended to be performed by the semiconductor device 100A. In at least one embodiment, the semiconductor device 100A further includes a non-circuit region, e.g., a sealing region, that extends around and protects the circuit region. Examples of active elements include, but are not limited to, transistors and diodes. Examples of transistors 125, 126 are described herein with respect to FIG. 1A. Examples of passive elements include, but are not limited to, capacitors, inductors, fuses, and resistors. A plurality of metal layers and via layers are alternatingly formed over the substrate 101 to electrically couple the elements of the semiconductor device 100A with each other and/or with external devices. The substrate 101 includes, in at least one embodiment, a silicon substrate. The substrate 101 includes, in at least one embodiment, silicon germanium (SiGe), Gallium arsenic, p-type doped Si, n-type doped Si, or suitable semiconductor materials. For example, semiconductor materials including group III, group IV, and group V elements are within the scope of various embodiments. In some embodiments, the substrate 101 further includes one or more other features, such as various doped regions, a buried layer, and/or an epitaxy (epi) layer. In some embodiments, the substrate 101 includes a semiconductor on insulator, such as silicon on insulator (SOI). In some embodiments, the substrate 101 includes a doped epi layer, a gradient semiconductor layer, and/or a semiconductor layer overlying another semiconductor layer of a different type such as a silicon layer on a silicon germanium layer.

The active regions 111 and 112 extend along the X-direction of the layout of the semiconductor device 100A. In some embodiments, the active regions 111 and 112 are also referred to as oxide-definition (OD) regions. Example materials of the active area regions 111 and 112 include, but are not limited to, semiconductor materials doped with various types of p-dopants and/or n-dopants. In at least one embodiment, the active regions 111 and 112 include dopants of the same type. In at least one embodiment, one of the active regions 111 and 112 includes dopants of a type different from a type of dopants of another one of the active regions 111 and 112. The active regions 111 and 112 may be isolated from each other by one or more gate isolation sections as described herein. In some embodiments, the active regions 111 and 112 are within corresponding well regions. For example, the active region 111 may be within a well region 113 which is an n-well region in one or more embodiments, and the active region 112 is within a well region 114 which is a p-well region in one or more embodiments. The described conductivity of the well regions 113 and 114 is an example. Other arrangements are within the scope of various embodiments.

The n-well region 113 and the p-well region 114 are on opposite sides of the imaginary line 110 which may divide the semiconductor device 100A into separate regions for different types of devices or transistors. Examples of transistors include, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), FinFETs, planar MOS transistors with raised source/drains, gate-all-around (GAA) transistors, nanosheet transistors, or the like. In the illustrated example of FIGS. 1A-1C, the n-well region 113 is a region for forming p-channel metal-oxide semiconductor (PMOS) transistors, and the p-well region 114 is a region for forming n-channel metal-oxide semiconductor (NMOS) transistors. The first and second active regions 111 and 112 respectively include a first circuit region 121 and a second circuit region 122, both extending in the X-direction. Each of the first circuit region 121 and the second circuit region 122 further includes at least one transistor. In the illustrated example, the first circuit region 121 includes a first transistor 125, and the second circuit region 122 includes a second transistor 126.

As illustrated in FIGS. 1A and 1C, the first transistor 125 includes a first gate electrode 117, a channel region 131, and two S/D regions 127a and 127b. The first gate electrode 117 is a section (e.g., a segment or a portion) of the gate structure 103 located in the first circuit region 121. For convenience, a “gate electrode” of a transistor, as used herein, is also referred to as a “gate electrode section” of a gate structure that connects to the transistor. The first gate electrode 117 is disposed on and in contact with the channel region 131. The two S/D regions 127a and 127b are respectively formed at the two opposite sides of the first gate electrode 117 and connected to the channel region 131. The first gate electrode 117 further includes a gate dielectric layer 133 and a gate metal layer 135. The gate dielectric layer 133 is directly coupled to the channel region 131, and the gate metal layer 135 is disposed on the gate dielectric layer 133. Likewise, the second transistor 126 includes a second gate electrode 118, a channel region 132, and two S/D regions 128a and 128b. The second gate electrode 118 is a portion of the gate structure 103 located in the second circuit region 122. The second gate electrode 118 is disposed on and in contact with the channel region 132. The two S/D regions 128a and 128b are respectively formed at the two opposite sides of the second gate electrode 118 and connected to the channel region 132. The gate electrodes 117 and 118 have a width (W₀) characterized by the distance between the two opposite sides in the X-direction.

The second gate electrode 118 further includes a gate dielectric layer 134 and a gate metal layer 136. The gate dielectric layer 134 is directly coupled to the channel region 132, and the gate metal layer 136 is disposed on the gate dielectric layer 134. Example materials of the gate metal layer 135, 136 include a metal or a polysilicon. In some embodiments, the metal of the gate electrodes 117 and 118 can be a work function metal such as tungsten (W), titanium nitride (TiN), titanium oxide (TiO), nickel silicide (NiSi), cobalt silicide (CoSi), hafnium (Hf), zirconium (Zr), aluminum (Al), and tantalum oxide (TaO). Other materials are within the scope of various embodiments. In some embodiments, the metal of the gate electrodes 117 and 118 has a relatively high resistivity, for example, at least 30 μΩ·cm, or at least 50 μΩ·cm, or at least 80 μΩ·cm. Non-limiting examples of the gate dielectric layer 133,134 include silicon dioxide, hafnium dioxide, aluminum oxide, silicon oxynitride (SiON), and so on. In some embodiments, the first and second transistors 125 and 126 are substantially aligned in the Y-direction. In some embodiments, two or more transistors are formed in each of the first and second circuit regions 121 and 122.

In some embodiments, two spacers (not shown) are formed and arranged along the sides (or boundaries) of the gate structure 103. The spacers may be disposed on the two opposite sides of both the gate electrodes 117 and 118 as well as the low-resistance section 140. The spacers may include one or more dielectric materials for electrically isolating the corresponding gate electrodes from unintended electrical contact. Example dielectric materials of the spacers include, but are not limited to, silicon nitride, silicon oxynitride, and silicon carbide. In at least one embodiment, one or more of the spacers have a tapered profile.

In some embodiments, the first and second transistors 125 and 126 are FinFETs. For example, a first fin 161 and a second fin 162 (as illustrated in FIG. 1A) may be respectively formed in the first and second circuit regions 121 and 122. The fins 161 and 162 may extend in the X-direction. The gate structure 103 may interconnect the fins 161 and 162. The channel region 131, two S/D regions 127a and 127b may be formed in the first fin 161; the channel region 132, two S/D regions 128a and 128b may be formed in the second fin 162. In some embodiments, two or more fins may be formed in each of the first and second circuit regions 121 and 122, and the resulting FinFETs may be a multiple-fin FinFET (MF-FinFET). The FinFET configuration described herein is an example. Other arrangements are within the scope of various embodiments. For example, in one or more embodiments, the transistors 125 and 126 may be a GAA transistor including a nanowire or a nanosheet surrounded by the gate electrode, and the channel region and S/D regions are formed on the corresponding nanowire or nanosheet.

One or more shallow trench isolation (STI) structures 102 are formed on the substrate 101. Example materials of the STI structure 102 include, but are not limited to, silicon oxide, silicon nitride, silicon oxynitride, fluoride-doped silicate glass (FSG), a low-K dielectric material, and/or combinations thereof. In an example, the formation of the STI structure 102 includes filling trenches between the fins, for example, by a chemical vapor deposition (CVD) process, with a dielectric material. In some embodiments, the filled trench has a multi-layer structure, such as a thermal oxide liner layer filled with silicon nitride or silicon oxide.

The semiconductor device 100A further includes an inter-layer dielectric (ILD) layer over the STI. In the example configuration in FIGS. 1A-1B, the semiconductor device 100A includes an inter-layer dielectric (ILD) layer 107 over the STI structure 102. Example materials of the ILD layer 107 include, but are not limited to, SiNx, SiOx, SiON, SiC, SiBN, SiCBN, or combinations thereof. In some embodiments, the ILD layer 107 is homogenous in composition and composed of a material having a relatively high dielectric constant and/or a relatively low dielectric strength. In some embodiments, the ILD layer 107 includes a dielectric material having a dielectric constant from 2 to 9, from 3 to 8, or from 4 to 7. In some embodiments, the ILD layer 107 includes a dielectric material having a dielectric strength from 0.001 V/μm to 0.02 V/μm, from 0.005 V/μm to 0.015 V/μm, or 0.005 V/μm to 0.01 V/μm. In other embodiments, the ILD layer 107 is heterogeneous in composition and may be composed of different materials that surround different elements of the semiconductor device (e.g., the example shown in FIG. 1F). In some embodiments, the ILD layer 107 embeds therein the gate structure 103. The ILD layer 107 further embeds therein the first and second circuit regions 121 and 122 of the active regions 111 and 112.

The semiconductor device 100A may further include one or more via contacts disposed on the gate structure 103. As illustrated in FIG. 1A, a via contact 151 may be disposed on the low-resistance section 140. The via contact 151 allows electrical connections between different layers or regions within the semiconductor device 100A.

The gate structure 103 extends along the Y-direction, across the active regions 111 and 112. The gate structure 103 may include a plurality of gate electrodes separated and isolated by the low-resistance section 140. For example, the gate structure 103 includes the first gate electrode 117 and the second gate electrode 118. As described above, the first gate electrode 117 or a portion thereof is located in the first circuit region 121 and is a constituent of the first transistor 125. Likewise, the second gate electrode 118 or a portion thereof is located in the second circuit region 122 and is a constituent of the second transistor 126.

In the gate structure 103 of FIG. 1A, the low-resistance section 140 is located between and accordingly separates and isolates the first and second electrodes 117 and 118. In some embodiments, the low-resistance section 140 extends across the boundary between the first and second active regions 111 and 112. The low-resistance section 140 extends in the Y-direction from a first end (or an upper end of FIG. 1A) 143 to a second end (or a bottom end of FIG. 1A) 144 and extends in the X-direction from a first side (or a first boundary) 141 to a second side (or a second boundary) 142. The low-resistance section 140 has a length (L) characterized by the distance between the first and second ends 143 and 144 in the Y-direction and a width (W) characterized by the distance between the first and second sides 141 and 142 in the X-direction. The low-resistance section 140 has a distance (D₁) from the interconnected transistors 125/126. D₁ is further characterized by the distance between the first end 143 and the S/D regions 127a/127b of the first transistor 125 or the distance between the second end 144 and the S/D regions 128a/128b of the second transistor 126.

In the illustrated example of FIG. 1A, the width (W) of the low-resistance section 140 is larger than the width (W₀) of the gate electrodes 117 and 118. In some embodiments, W is at least 10% more than W₀. In some embodiments, a ratio of W to W₀ (W/W₀) is at least 2, at least 3, at least 4, or at least 5. In some embodiments, W/W₀ is equal to or less than 5. In some embodiments, W/W₀ is between 1.1 and 5. In some embodiments, a ratio of L to W₀ (L/W₀) is at least 5, at least 10, or at least 20. In some embodiments, a ratio of D₁ to W₀ (D₁/W₀) is at least 2, at least 3, or at least 5. A minimum distance between the low-resistance section and the interconnected transistors may minimize the interference with the transistors and ensure the proper function of the gate electrodes of the transistors.

As described above, the low-resistance section 140 and the gate electrodes 117 and 118 are constituting sections of the gate structure 103. In some embodiments, the low-resistance section 140 is composed of a material that is the same or similar to the material of the gate electrodes 117 and 118. However, due to the larger width of the low-resistance section 140, the cross-sectional dimension (i.e., the cross-sectional area of the X-Z plane) of the low-resistance section 140 is larger compared with the first and second gate electrodes 117 and 118. Accordingly, the resistance of the heterogeneous gate structure 103 having the low-resistance section 140 can be significantly reduced compared with a homogenous gate structure without the low-resistance section 140 between the two gate electrodes. In some embodiments, the resistance of the heterogeneous gate structure 103 has a resistance reduction of at least 10%, at least 23%, at least 30%, at least 40%, at least 50%, or at least 75%, as compared with a homogenous gate structure without the low-resistance section 140.

FIG. 1D is a top view of a layout of a semiconductor device 100D, in accordance with some embodiments. FIG. 1E is a cross-sectional view of the semiconductor device 100D along an imaginary line 120 from B to B′ in the Y-direction. The semiconductor device 100D is a close variation of the semiconductor device 100A. In the illustrated example of FIGS. 1D-1E, the low-resistance section 140 of the semiconductor device 100D includes a material that is different from the material of the gate electrodes 117 and 118. The low-resistance section 140 may be composed of a material of low resistivities such as metal, metal alloy, or metal compound. Non-limiting examples of the low-resistivity material include gold (Au), silver (Ag), rhodium (Rh), tungsten (W), molybdenum (Mo), zinc (Zn), cobalt (Co), ruthenium (Ru), niobium (Nb), titanium (Ti), zirconium (Zr), brass, titanium nitride (TiN), phosphor bronze, cast steel, and so on. Other materials having a relatively low resistivity are also within the scope of the present disclosure.

In some embodiments, the gate electrodes 117 and 118 are composed of a first material, and the low-resistance section 140 is composed of a second material different from the first material. In some embodiments, the first material has a first resistivity, the second material has a second resistivity, and the second resistivity is less than the first resistivity. In some embodiments, the second resistivity is less than 100μΩ·cm, or less than 50μΩ·cm, or less than 30μΩ·cm, or less than 10μΩ·cm.

In the example of FIG. 1D, the low-resistance section 140 has both an enlarged cross-sectional dimension and a low-resistivity material. Accordingly, the overall resistance of the gate structure 103 may be further lowered, as compared to the conventional gate structure without the low-resistance section 140.

FIG. 1F is a top view of a layout of a semiconductor device 100F, in accordance with some embodiments. FIG. 1G is a cross-sectional view of the semiconductor device 100F along the imaginary line 110 from A to A′ in the X-direction. The semiconductor device 100F is a close variation of the semiconductor devices 100A and 100D. In the illustrated example of FIGS. 1F-1G, the ILD layer 107 is heterogeneous and further includes a first ILD structure 108 and a second ILD structure 109. The first and second gate electrodes 117 and 118 are respectively surrounded by the first ILD structure 108 (i.e., the first ILD structure 108 respectively isolates the first and second gate electrodes 117 and 118 from other conductive elements in the semiconductor device 100F). The low-resistance section 140 is surrounded by the second ILD structure 109 (i.e., the second ILD structure 109 isolates the low-resistance section 140 from other conductive elements in the semiconductor device 100F). As described above, the first ILD structure 108 may be composed of silicon dioxide. The second ILD structure 109 may be composed of a material that is different from the material of the first ILD structure 108. In some embodiments, the second ILD structure 109 includes a material that has a relatively low dielectric constant (K) and/or a relatively high dielectric strength. Non-limiting examples of the material of the second ILD structure 109 include Fluorine-doped Silicon Dioxide, Carbon-doped Silicon Dioxide, Organosilicate Glass, Porous Silicon Dioxide, Fused Silica, Mica, Polyethylene, Alumina, Borosilicate glass, Air Gap, and so on.

In some embodiments, the first ILD structure 108 has a first dielectric constant and a first dielectric strength, and the second ILD structure 109 has a second dielectric constant and a second dielectric strength. In some embodiments, the second dielectric constant is lower than the first dielectric constant. In some embodiments, the second dielectric strength is higher than the first dielectric constant. In some embodiments, the second dielectric constant is lower than the dielectric constant of silicon dioxide. In some embodiments, the second dielectric constant is less than 4, less than 3.9, less than 3, or less than 2. In some embodiments, the second dielectric strength is higher than 0.001 V/μm, or higher than 1 V/μm, or higher than 10 V/μm, or higher than 100 V/μm, or higher than 400 V/μm. The low dielectric constant and/or high dielectric strength of the second ILD structure 109 surrounding the low-resistance section 140 may contribute to the reduction or prevention of parasitic capacitance between the low-resistance section 140 and another conductive element (e.g., another low-resistance section or a metal contact) adjacent to or in proximity to the low-resistance section 140. Accordingly, the combination of the low dielectric constant of the second ILD structure 109 and the low-resistivity material of the low-resistance section 140 may further improve the overall performance of the semiconductor device 100F.

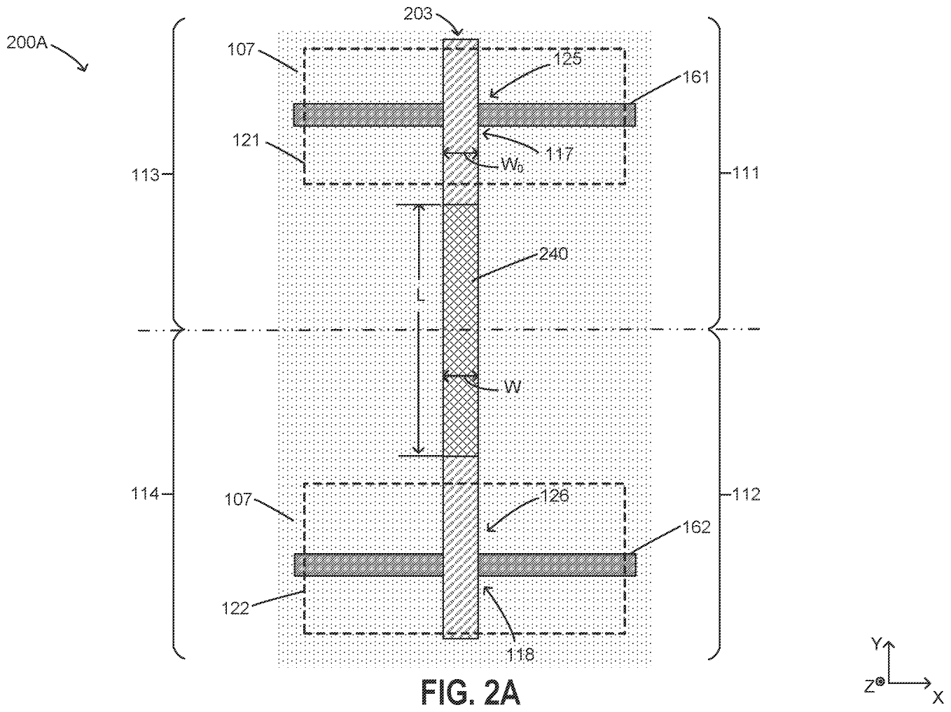

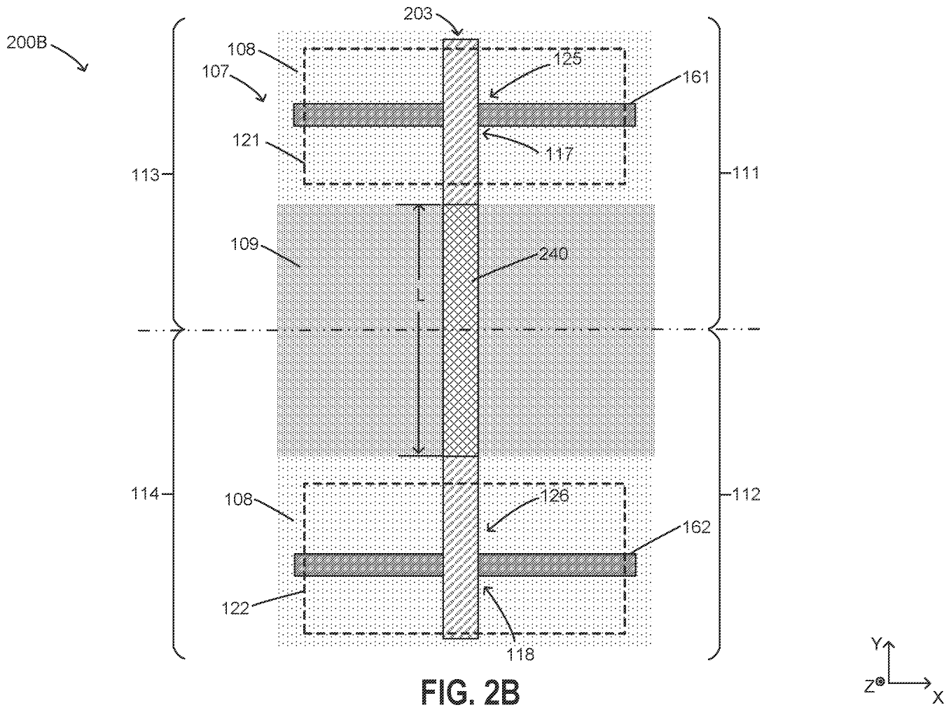

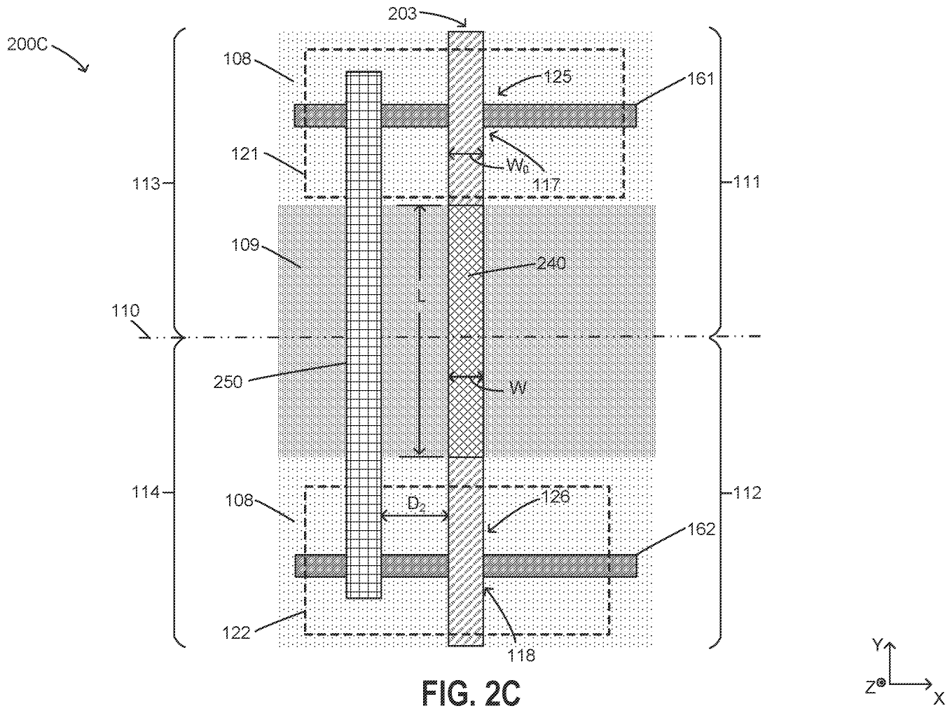

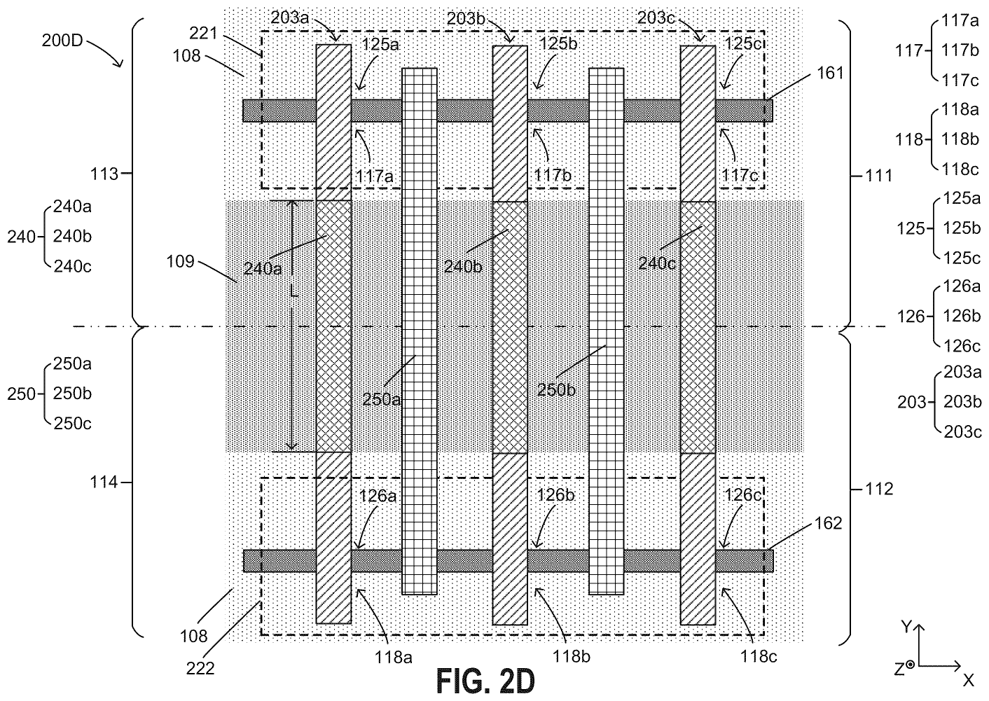

FIG. 2A is a top view of a layout of a semiconductor device 200A, in accordance with some embodiments. The semiconductor device 200A is a close variation of the semiconductor device 100A. In the illustrated example, the semiconductor device 200A includes a first transistor 125, a second transistor 126, and a gate structure 203 interconnecting the first and second transistors 125/126. The gate structure 203 includes a first gate electrode 117 corresponding to the first transistor 125, a second gate electrode 118 corresponding to the second transistor 126, and a low-resistance section 240 between the first and second gate electrodes 117 and 118. The low-resistance section 240 has a width (W) that is substantially the same as the width (W₀) of the gate electrodes 117 and 118. In other words, the gate structure 203 has a substantially uniform width in the Y-direction. However, the low-resistance section 240 is composed of a material that is different from the material of the gate electrodes 117 and 118. In some embodiments, the material of the low-resistance section 240 has a lower resistivity than the material of the gate electrodes 117 and 118. Due to the low-resistivity material of the low-resistance section 240, the overall resistance of the gate structure 203 may be lowered, as compared to the conventional gate structure without the low-resistance section 240.

FIG. 2B is a top view of a layout of a semiconductor device 200B, in accordance with some embodiments. The semiconductor device 200B is a close variation of the semiconductor device 200A. In the illustrated example, the ILD layer 107 of the semiconductor device 200B further includes a first ILD structure 108 and a second ILD structure 109, in a similar manner as the semiconductor device 100F. The gate electrodes 117 and 118 are respectively surrounded by the first ILD structure 108, while the low-resistance section 240 is surrounded by the second ILD structure 109. The second ILD structure 109 is composed of a material having a relatively low dielectric constant. In some embodiments, the first ILD structure 108 has a first dielectric constant, and the second ILD structure 109 has a second dielectric constant. The second dielectric constant is lower than the first dielectric constant. The combination of the low dielectric constant of the second ILD structure 109 and the low-resistivity material of the low-resistance section 240 may further improve the overall performance of the semiconductor device 200B.

FIG. 2C is a top view of a layout of a semiconductor device 200C, in accordance with some embodiments. The semiconductor device 200C is a close variation of the semiconductor devices 200A and 200B. In the illustrated example, the semiconductor device 200C further includes a metal contact 250. Metal contacts used herein are sometimes also referred to as “metal on operation domain” or “MD.” The metal contact 250 extends in the same direction as the gate structure 203 (i.e., the Y-direction) across the boundary (i.e., the line 110) between the first active region 111 and the second active region 112. The metal contact 250 is configured to interconnect the first and second transistors 125 and 126 and electrically couple the underlying S/D regions of the first and second transistors 125 and 126 with each other or with other circuitry of the semiconductor device 200C. The metal contact 250 is adjacent to the gate structure 203. In some embodiments, the metal contact 250 is proximate to the adjacent gate structure 203 with a limited distance therebetween (D₂). In some embodiments, a ratio of D₂/W₀ is no more than 5, no more than 3, no more than 2, or no more than 1. In some embodiments, the ratio of D₂/W₀ is from 0.5 to 3, or from 1 to 2. Due to the proximity between the metal contact 250 and the gate structure 203, the low-resistance section 240 may not have an enlarged dimension (i.e., a larger W than W₀). However, the overall resistance of the gate structure 203 may still be lowered by the low-resistivity material of the low-resistance section 240.

In some embodiments, the low-resistance section 240 is surrounded by the second ILD structure 109 composed of a dielectric material different from the material of the first ILD structure 108. As described in the example of FIG. 1F, the dielectric material of the second ILD structure 109 may have a relatively low dielectric constant and a relatively high dielectric strength, which could contribute to the reduction or prevention of the parasitic capacitance between the low-resistance section 240 and the metal contact 250 adjacent to it. In addition, the relatively high dielectric strength of the second ILD structure 109 may also effectively prevent electric breakdown between the low-resistance section 240 and the metal contact 250.

FIG. 2D is a top view of a layout of a semiconductor device 200D, in accordance with some embodiments. The semiconductor device 200D is a close variation of the semiconductor device 200C. In the illustrated example, the semiconductor device 200D includes, among other components, multiple transistors 125a, 125b, 125c (collectively as transistors 125) in the first circuit region 221, multiple transistors 126a, 126b, 126c (collectively as transistors 126) in the second circuit region 222, multiple gate structures 203a, 203b, and 203c (collectively as gate structures 203), and multiple metal contacts 250a and 250b (collectively as metal contacts 250).

The multiple gate structures 203a, 203b, and 203c respectively interconnect the transistors 125a and 126a, transistors 125b and 126b, and transistors 125c and 126c. The gate structure 203a further includes two gate electrodes 117a and 118a as well as a low-resistance section 240a between the two gate electrodes 117a and 118a. Likewise, the gate structure 203b further includes two gate electrodes 117b and 118b as well as a low-resistance section 240b between the two gate electrodes 117b and 118b, and the gate structure 203c further includes two gate electrodes 117c and 118c as well as a low-resistance section 240c between the two gate electrodes 117c and 118c. The gate electrodes 117a, 117b, and 117c are collectively labeled as gate electrodes 117, and the gate electrodes 118a, 118b, and 118c are collectively labeled as gate electrodes 118.

The multiple metal contacts 250a and 250b are respectively disposed between the gate structures 203a and 203b and between the gate structures 203b and 203c. As illustrated, due to the proximity between every two adjacent gate structures 203 (e.g., the gate structures 203a and 203b, or the gate structures 203b and 203c) the low-resistance sections 240 may be limited in width for the metal contacts 250 to be accommodated between the two adjacent gate structures 203. In some embodiments, the low-resistance sections 240 may have a width that is substantially the same as the width of the gate electrodes 117 and 118.

In the example of FIG. 2D, the dielectric material of the second ILD structure 109 may have a relatively low dielectric constant and a relatively high dielectric strength, which could contribute to the reduction or prevention of the parasitic capacitance between each of the two low-resistance sections (e.g., the low-resistance section 240a/240b) and the metal contact (e.g., the metal contact 250a) disposed therebetween.

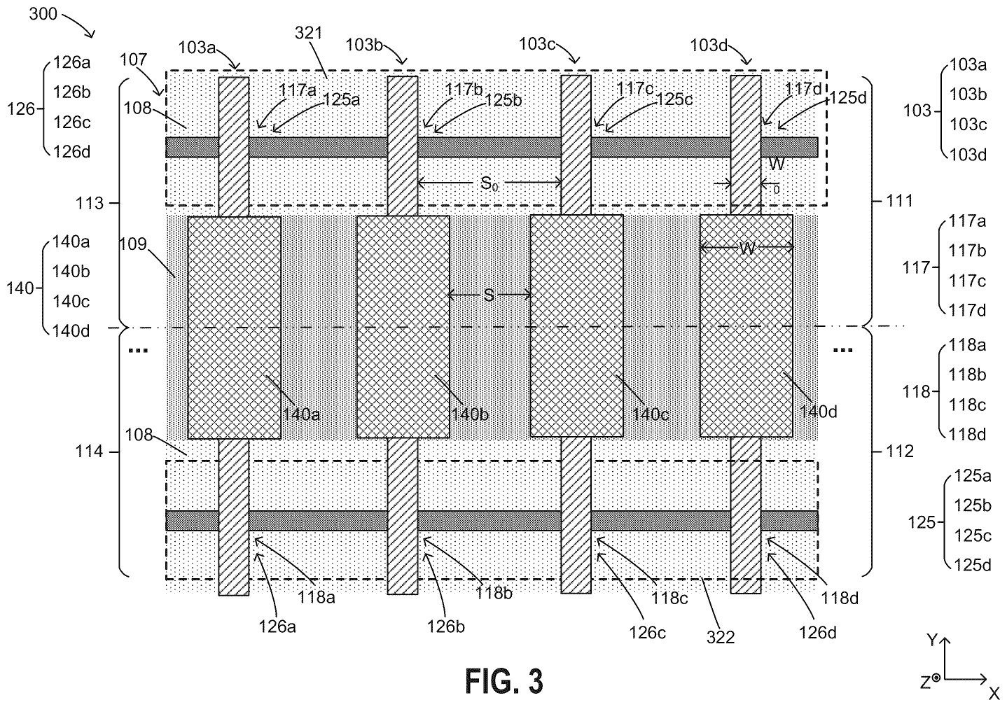

FIG. 3 is a top view of a layout of a semiconductor device 300, in accordance with some embodiments. The semiconductor device 300 is a close variation of the semiconductor devices 100A, 100D, and 100F. In the illustrated example, the semiconductor device 300 includes, among other components, multiple transistors 125a, 125b, 125c, 125d (collectively as transistors 125) in the first circuit region 321, multiple transistors 126a, 126b, 126c, 126d (collectively as transistors 126) in the second circuit region 322, and multiple gate structures 103a, 103b, 103c, 103d (collectively as gate structures 103). For simplicity, some components such as spacers and via contacts are not shown in FIG. 3. It should be noted that the number of gate structures 103 may vary depending on design requirements.

The multiple gate structures 103a, 103b, 103c, 103d extend in the Y-direction and respectively interconnect the transistors 125a and 126a, transistors 125b and 126b, transistors 125c and 126c, and transistors 125d and 126d. The gate structure 103a further includes two gate electrodes 117a and 118a as well as a low-resistance section 140a between the two gate electrodes 117a and 118a. Likewise, the gate structure 103b further includes two gate electrodes 117b and 118b as well as a low-resistance section 140b between the two gate electrodes 117b and 118b; the gate structure 103c further includes two gate electrodes 117c and 118c as well as a low-resistance section 140c between the two gate electrodes 117c and 118c; the gate structure 103d further includes two gate electrodes 117d and 118d as well as a low-resistance section 140d between the two gate electrodes 117d and 118d. The gate electrodes 117a, 117b, 117c, and 117d are collectively labeled as gate electrodes 117; the gate electrodes 118a, 118b, 118c, and 118d are collectively labeled as gate electrodes 118; the low-resistance section 140a, 140b, 140c, and 140d are collectively labeled as low-resistance sections 140. The low-resistance sections 140 are similar to the low-resistance sections 140 shown in FIGS. 1A-1G.

In some embodiments, the two low-resistance sections 140 are substantially aligned in the X-direction. Every two adjacent gate structures 103 (e.g., the gate structures 103b and 103c) may have a distance (S₀) characterized by the distance between the corresponding gate electrode sections in the same circuit region (e.g., the gate electrodes 117b and 117c in the first circuit region 321) in the X-direction. Every two adjacent gate structures 103 may have a spacing(S) characterized by the distance between the corresponding low-resistance sections 140 (e.g., the low-resistance sections 140b and 140c). As described above, the gate structure 103 may have a width (W₀) characterized by the width of the gate electrode in the X-direction. The low-resistance section 140 may have a width (W) characterized by the distance between the two opposite sides thereof. In some embodiments, W is at least 10% more than W₀. In some embodiments, a ratio of W to W₀ (W/W₀) is at least 2, at least 3, at least 4, or at least 5. In some embodiments, W/W₀ is equal to or less than 5. In some embodiments, W/W₀ is from 1.1 to 5. In some embodiments, S is at least 10% less than S₀. In some embodiments, a ratio of S/S₀ is no more than 0.9, no more than 0.6, or no more than 0.3. In some embodiments, S is equal to or more than W₀. In some embodiments, a ratio of S/W₀ is at least 1, at least 2, or at least 3. In some embodiments, S₀, W₀, and S satisfy the following relationship: 0.9*S₀≥S≥W₀. In some embodiments, S is at least 3 nm, at least 5 nm, at least 10 nm, or at least 15 nm. A minimum distance between every two adjacent low-resistance sections may ensure the proper function of the gate structure and minimize the risk of electrical breakdown between the adjacent low-resistance sections.

It should be noted that the values of W₀, W, S₀, and S may vary depending on design requirements. In some embodiments, the values of W₀, W, S₀, and S may be uniform or substantially uniform across the semiconductor device 300. In some embodiments, the values of W, S₀, and S may vary across the semiconductor device 300. In some embodiments, a sum of the W of low-resistance section (e.g., the low-resistance section 140d) and the adjacent spacing S may be a constant (e.g., sum of the W₀ of gate electrode sections 117d and S₀ between the two corresponding gate electrode sections 117c and 117d). In other words, for each heterogenous gate structure 103 and an adjacent spacing S that are substantially the same, the W₀, W, S₀, and S of the heterogenous gate structures 103 and the adjacent spacing S may satisfy the following relationships: W+S=constant, or W+S=W₀+S₀.

In some embodiments, the low-resistance sections 140 may be composed of a material that is the same as or similar to the material of the gate electrodes 117 and 118. In some embodiments, the low-resistance sections 140 may be composed of a material that is different from the material of the gate electrodes 117 and 118. In some embodiments, the material of the low-resistance sections 140 may be a low-resistivity material. In some embodiments, the material of gate electrodes 117 and 118 has a first resistivity, and the material low-resistance sections 140 has a second resistivity. The second resistivity is less than the first resistivity.

In some embodiments, the ILD layer 107 of the semiconductor device 300 further includes a first ILD structure 108 and a second ILD structure 109, in a similar manner as the semiconductor device 100F. The gate electrodes 117 and 118 are respectively surrounded by the first ILD structure 108. The low-resistance sections 140 are surrounded by the second ILD structure 109. The second ILD structure 109 is composed of a material that is different from the material of the first ILD structure 108. In some embodiments, the second ILD structure 109 includes a material that has a relatively low dielectric constant (K) and/or a relatively high dielectric strength.

In some embodiments, the first ILD structure 108 has a first dielectric constant and a first dielectric strength, and the second ILD structure 109 has a second dielectric constant and a second dielectric strength. In some embodiments, the second dielectric constant is lower than the first dielectric constant. In some embodiments, the second dielectric strength is higher than the first dielectric constant. In some embodiments, the second dielectric constant is lower than the dielectric constant of silicon dioxide. In some embodiments, the second dielectric constant is less than 3.9. In some embodiments, the second dielectric strength is higher than 0.001 V/μm. In some embodiments, the low dielectric constant and/or high dielectric strength of the second ILD structure 109 between the two adjacent low-resistance sections (e.g., the low-resistance sections 140a and 140b) may contribute to the reduction or prevention of parasitic capacitance between the two low-resistance sections that are in proximity to each other. In addition, the relatively high dielectric strength of the second ILD structure 109 may also effectively prevent electric breakdown between the two adjacent low-resistance sections 140. Accordingly, the combination of the low dielectric constant of the second ILD structure 109 and the low-resistivity material of the low-resistance sections 140 may further improve the overall performance of the semiconductor device 300.

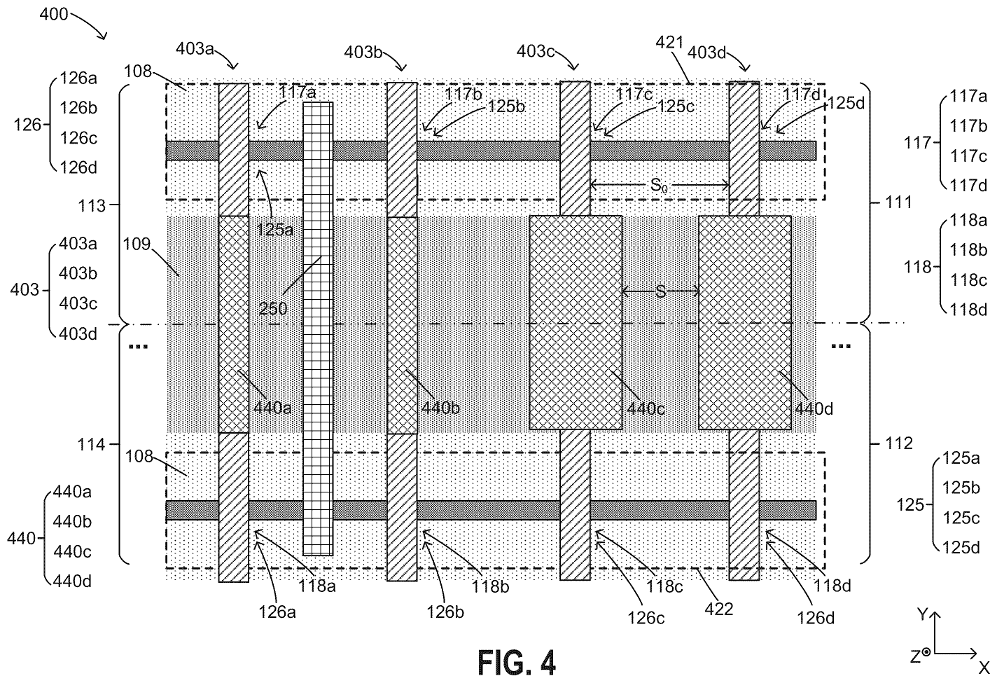

FIG. 4 is a top view of a layout of a semiconductor device 400, in accordance with some embodiments. The semiconductor device 400 is a variation of the semiconductor devices 200D and 300 and may include various configurations and combinations of elements as described above. In the illustrated example, the semiconductor device 400 includes, among other components, multiple transistors 125a, 125b, 125c, 125d (collectively as transistors 125) in the first circuit region 421, multiple transistors 126a, 126b, 126c, 126d (collectively as transistors 126) in the second circuit region 422, multiple gate structures 403a, 403b, 403c, 403d (collectively as gate structures 403), and a metal contact 250 disposed between the gate structures 403a and 403b.

The multiple gate structures 403a, 403b, 403c, 403d extend in the Y-direction and respectively interconnect the transistors 125a and 126a, transistors 125b and 126b, transistor 125c and 126c, and transistors 125d and 126d. The gate structures 403a and 403b are similar to the gate structure 203 of FIG. 2A. For example, the gate structure 403a further includes two gate electrodes 117a and 118a as well as a low-resistance section 440a between the two gate electrodes 117a and 118a. Likewise, the gate structure 403b further includes two gate electrodes 117b and 118b as well as a low-resistance section 440b between the two gate electrodes 117b and 118b. The gate structures 403c and 403d are similar to the gate structure 103 of FIG. 1A. For example, the gate structure 403c further includes two gate electrodes 117c and 118c as well as a low-resistance section 440c between the two gate electrodes 117c and 118c; the gate structure 403d further includes two gate electrodes 117d and 118d as well as a low-resistance section 440d between the two gate electrodes 117d and 118d. The gate electrodes 117a, 117b, 117c, and 117d are collectively labeled as gate electrodes 117; the gate electrodes 118a, 118b, 118c, and 118d are collectively labeled as gate electrodes 118; the low-resistance section 440a, 440b, 440c, and 440d are collectively labeled as low-resistance sections 440.

The metal contact 250 is disposed between the gate structures 403a and 403b. Similar to the metal contact 250 of FIG. 2C, the metal contact 250 of FIG. 4 is configured to interconnect the transistors 125a/125b and 126a/126b and electrically couple the underlying S/D regions of the transistors 125a/125b and 126a/126b with each other or with other circuitry of the semiconductor device 400. The metal contact 250 is adjacent to the gate structures 403a and 403b. Due to the proximity between the metal contact 250 and the gate structures 403a and 403b, the low-resistance sections 440a and 440b may not have an enlarged dimension (i.e., a larger W than W₀). However, the overall resistance of the gate structures 403a and 403b may still be lowered by the low-resistivity material of the low-resistance sections 440a and 440b. As described in the example of FIG. 2D, the dielectric material of the second ILD structure 109 may have a relatively low dielectric constant and a relatively high dielectric strength, which could contribute to the reduction or prevention of the parasitic capacitance between each of the two low-resistance sections 440a/440b and the metal contact 250 disposed therebetween.

By contrast, the low-resistance sections 440c and 440d of the gate structures 403c and 403d have an enlarged width (e.g., W is larger than W₀) and an enlarged cross-sectional dimension. In some embodiments, the low-resistance sections 440c and 440d may further include a material (e.g., a material with relatively lower resistivity) different from the material of the gate electrodes 117 and 118. Due to the proximity of the low-resistance sections 440c and 440d, no metal contact is disposed therebetween. Because of the multiple low-resistance sections 440, the overall performance of the semiconductor device 400 may be significantly improved.

In some embodiments, the layout of the semiconductor devices described herein is represented by a plurality of masks generated by one or more processors and/or stored in one or more non-transitory computer-readable media. Other formats for representing the layout of the semiconductor devices are within the scope of various embodiments. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like. For example, the layout of the semiconductor device 400 is presented by at least one first mask corresponding to the active regions 111 and 112, at least one second mask corresponding to the gate structures 403a and 403b, at least one third mask corresponding to the gate structures 403c and 403d, at least one fourth mask corresponding to the low-resistance sections 440a and 440b, at least one fifth mask corresponding to the low-resistance sections 440a and 440b, at least one sixth mask corresponding to the low-resistance sections 440c and 440d, and at least one seventh mask corresponding to the metal contact 250.

### SUMMARY

In accordance with some aspects of the disclosure, semiconductor devices are provided. In one example, a semiconductor device includes: a substrate, a first circuit region and a second circuit region formed over the substrate and extending in a first direction, a first transistor located in the first circuit region. The first transistor includes a first gate electrode extending in a second direction, and the second direction is substantially perpendicular to the first direction. The semiconductor device further includes a second transistor located in the second circuit region. The second transistor includes a second gate electrode extending in the second direction and aligned with the first gate electrode in the second direction. The semiconductor device further includes a low-resistance section extending in the second direction and interconnecting the first and second gate electrodes. The low-resistance section is substantially aligned with the first and second gate electrodes in the second direction. The first and second gate electrodes have a first width (W₀) along the first direction, the low-resistance section has a second width (W) along the first direction, and a ratio of W to W₀ (W/W₀) is at least 1.1.

In another example, a semiconductor device includes a substrate, a first circuit region and a second circuit region formed over the substrate and extending in a first direction, and a gate structure extending in a second direction that is substantially perpendicular to the first direction. The gate structure further includes: two gate electrode sections respectively located in the first and second circuit regions, and a low-resistance section between and interconnecting the two gate electrode sections. The two gate electrode sections are configured as gate electrodes for two transistors respectively located in the first and second circuit regions. The two gate electrode sections include a first material having a first resistivity, the low-resistance section includes a second material having a second resistivity, and the second resistivity is less than the first resistivity.

In yet another example, a semiconductor device includes a substrate, a first circuit region and a second circuit region formed over the substrate and extending in a first direction, and a plurality of gate structures extending in a second direction that is substantially perpendicular to the first direction. The plurality of gate structures further includes a first gate structure and a second gate structure adjacent to each other. The first gate structure further includes: a first gate electrode section and a second gate electrode section respectively located in the first and second circuit regions, and a first low-resistance section between and interconnecting the first and second gate electrode sections. The first and second gate electrode sections are configured as gate electrodes for a first transistor and a second transistor respectively located in the first and second circuit regions. The second gate structure further includes a third gate electrode section and a fourth gate electrode section respectively located in the first and second circuit regions, and a second low-resistance section between and interconnecting the third and fourth gate electrode sections. The third and fourth gate electrode sections are configured as gate electrodes for a third transistor and a fourth transistor respectively located in the first and second circuit regions. The first, second, third, and fourth gate electrode sections of the first and second gate structures have a first width (W₀) along the first direction, the first and second low-resistance sections have a second width (W) along the first direction, and a ratio of W to W₀ (W/W₀) is at least 1.1.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate;
a first circuit region and a second circuit region formed over the substrate and extending in a first direction;
a first transistor located in the first circuit region, the first transistor comprising a first gate electrode extending in a second direction, the second direction being substantially perpendicular to the first direction;
a second transistor located in the second circuit region, the second transistor comprising a second gate electrode extending in the second direction and aligned with the first gate electrode in the second direction; and
a low-resistance section extending in the second direction and interconnecting the first and second gate electrodes, wherein the low-resistance section is substantially aligned with the first and second gate electrodes in the second direction,
wherein the first and second gate electrodes have a first width (W₀) along the first direction, the low-resistance section has a second width (W) along the first direction, and a ratio of W to W₀ (W/W₀) is at least 1.1.

2. The semiconductor device of claim 1, wherein the ratio of W to W₀ (W/W₀) is from 1.1 to 5.

3. The semiconductor device of claim 1, wherein the low-resistance section has a length (L) along the second direction, and a ratio of L to W₀ (L/W₀) is at least 10.

4. The semiconductor device of claim 1, wherein the low-resistance section extends from a first end to a second end in a direction from the first transistor to the second transistor, the first transistor includes two source/drain (S/D) regions at two opposite sides of the first gate electrode, the low-resistance section has a distance (D₁) between the first end and the two S/D regions along the second direction, and a ratio of D₁ to W₀ (D₁/W₀) is at least 3.

5. The semiconductor device of claim 1, wherein the first and second gate electrodes comprise a first material having a first resistivity, the low-resistance section comprises a second material having a second resistivity, and the second resistivity is less than the first resistivity.

6. The semiconductor device of claim 1, wherein each of the first and second gate electrodes further comprises:
a gate dielectric layer disposed on and in contact with a channel region of the corresponding transistor; and
a gate metal layer disposed on the gate dielectric layer.

7. The semiconductor device of claim 1, wherein the first circuit region is located in a first active region, the second circuit region is located in a second active region, and the low-resistance section extends across a boundary between the first active region and the second active region.

8. The semiconductor device of claim 1, further comprising:
a first ILD structure comprising a first dielectric material; and
a second ILD structure comprising a second dielectric material,
wherein the first and second gate electrodes are surrounded by the first ILD structure, and the low-resistance section is surrounded by the second ILD structure,
wherein the second dielectric material is different from the first dielectric material.

9. A semiconductor device, comprising:
a substrate;
a first circuit region and a second circuit region formed over the substrate and extending in a first direction;
a gate structure extending in a second direction, the second direction being substantially perpendicular to the first direction, wherein the gate structure further comprises:
two gate electrode sections respectively located in the first and second circuit regions, the two gate electrode sections being configured as gate electrodes for two transistors respectively located in the first and second circuit regions; and
a low-resistance section between and interconnecting the two gate electrode sections,
wherein the two gate electrode sections comprise a first material having a first resistivity, the low-resistance section comprises a second material having a second resistivity, and the second resistivity is less than the first resistivity.

10. The semiconductor device of claim 9, wherein the two gate electrode sections and the low-resistance section have substantially the same width along the first direction.

11. The semiconductor device of claim 9, wherein the second resistivity is less than 100μΩ·cm.

12. The semiconductor device of claim 9, wherein the second material comprises at least one of gold (Au), silver (Ag), rhodium (Rh), tungsten (W), molybdenum (Mo), zinc (Zn), cobalt (Co), ruthenium (Ru), niobium (Nb), titanium (Ti), zirconium (Zr), brass, titanium nitride (TiN), phosphor bronze, and cast steel.

13. A semiconductor device comprising:
a substrate;
a first circuit region and a second circuit region formed over the substrate and extending in a first direction;
a plurality of gate structures extending in a second direction, the second direction being substantially perpendicular to the first direction, the plurality of gate structures including a first gate structure and a second gate structure adjacent to each other,
wherein the first gate structure further comprises:
a first gate electrode section and a second gate electrode section respectively located in the first and second circuit regions, the first and second gate electrode sections being configured as gate electrodes for a first transistor and a second transistor respectively located in the first and second circuit regions; and
a first low-resistance section between and interconnecting the first and second gate electrode sections;
wherein the second gate structure further comprises:
a third gate electrode section and a fourth gate electrode section respectively located in the first and second circuit regions, the third and fourth gate electrode sections being configured as gate electrodes for a third transistor and a fourth transistor respectively located in the first and second circuit regions; and
a second low-resistance section between and interconnecting the third and fourth gate electrode sections,
wherein the first, second, third, and fourth gate electrode sections of the first and second gate structures have a first width (W₀) along the first direction, the first and second low-resistance sections have a second width (W) along the first direction, and a ratio of W to W₀ (W/W₀) is at least 1.1.

14. The semiconductor device of claim 13, wherein the first and second low-resistance sections are substantially aligned in the first direction.

15. The semiconductor device of claim 13, wherein the gate electrode sections of the first and second gate structures comprise a first material having a first resistivity, and the first and second low-resistance sections comprise a second material having a second resistivity, wherein the second resistivity is less than the first resistivity.

16. The semiconductor device of claim 13, wherein the first and second gate structures are apart from each other by a first distance (S₀) measured between the corresponding gate electrode sections in the first direction and by a second distance(S) measured between the first and second low-resistance sections in the first direction, wherein a ratio of S to S₀ (S/S₀) is no more than 0.9.

17. The semiconductor device of claim 16, wherein S is at least 10 nm.

18. The semiconductor device of claim 16, wherein a ratio of S to W₀ (S/W₀) is at least 1.

19. The semiconductor device of claim 15, wherein the plurality of gate structures further includes a third gate electrode section adjacent to the first gate structure and extending in the second direction, wherein the third gate structure has the first width (W₀) along the second direction and further comprises:
a fifth gate electrode section and a sixth gate electrode section respectively located in the first and second circuit regions, the fifth and sixth gate electrode sections being configured as gate electrodes for a fifth transistor and a sixth transistor respectively located in the first and second circuit regions; and
a third low-resistance section between and interconnecting the fifth and sixth gate electrode sections, the third low-resistance section being substantially aligned with the first and second low-resistance sections in the first direction,
wherein the fifth and sixth gate electrode sections of the third gate structure comprise the first material, and the third low-resistance section comprises the second material.

20. The semiconductor device of claim 19, further comprising a metal contact extending in the second direction, the metal contact interconnecting the first and second circuit region, wherein the metal contact is adjacent to the third gate structure, and the third gate structure is between the metal contact and the first gate structure in the first direction.
